(19) United States
(12) Patent Application Publication
(10) Pub. No.: US 2008/0118743 A1
(43) Pub. Date: May 22, 2008

(54) DEPOSITION MASK, METHOD OF MANUFACTURING THE SAME, AND METHOD OF MANUFACTURING ELECTROLUMINESCENT DISPLAY DEVICE HAVING THE SAME

(75) Inventors: Joo Hyeon LEE, Yongin-si (KR); Chang Mo PARK, Seoul (KR)

Correspondence Address: H.C. PARK & ASSOCIATES, PLC, 8500 LEESBURG PIKE, SUITE 7500, VIENNA, VA, 22182, US

(73) Assignee: SAMSUNG ELECTRONICS CO., LTD., Suwon-si (KR)

(21) Appl. No.: 11/867,910

(22) Filed: Oct. 5, 2007

(30) Foreign Application Priority Data
Nov. 21, 2006 (KR) 10-2006-0115118

(51) Int. Cl. G11B 11/105; H01J 9/02; H01J 9/14

(52) U.S. Cl. 428/332; 445/24; 445/29

(57) ABSTRACT

A mask for depositing an organic film includes a mask sheet having at least two openings with different sizes and a blocking part formed in a region where the at least two openings are not formed. A supporting frame is formed on a back side of the mask sheet to support the mask sheet, and a mask frame receives a peripheral region of the supporting frame and supports a vertical pressure applied to the supporting frame and the mask sheet.

### CROSS-REFERENCE TO RELATED APPLICATION

This application claims priority to and the benefit of Korean Patent Application No. 10-2006-0115118, filed on Nov. 21, 2006, which is hereby incorporated by reference for all purposes as if fully set forth herein.

### BACKGROUND OF THE INVENTION

1. Field of the Invention

The present invention relates to a deposition mask and a method of manufacturing the same, and more particularly, to a deposition mask that may prevent a mask sheet from bending and a method of manufacturing the same.

2. Discussion of the Background

An organic electroluminescent (“EL”) display device is a self-emitting display device. The organic EL display device has a wide viewing angle, good contrast characteristics, and a fast response time, thereby attracting public attention as a promising display device.

A method of manufacturing the organic EL display device may include forming an insulation substrate to form an inorganic thin film pattern and depositing an organic material in a gas phase by heating the organic material from a depositing source. A large-sized mask may be used to deposit the organic material onto the substrate in a desired shape.

The large-sized mask for depositing the organic layer may be arranged under the substrate, and it may include a mask sheet defining a pattern to be formed and a mask frame supporting the mask sheet. The mask sheet may include a thin film. The mask frame may support an edge of the mask sheet, and it may have a rectangular shape with a cavity in the center.

A large, conventional mask may be configured such that the outermost region of the mask sheet having a plurality of openings of the same size is attached to the mask frame. However, the center of the mask may bend toward the mask frame due to gravity. Accordingly, the mask sheet may be deformed such that a pattern to be deposited may form an unintended shape. As a result, a pattern of the organic material may be deformed.

Further, the outermost region of the mask sheet may be attached to the mask frame by welding or other appropriate methods so that the mask sheet can be fixed to the mask frame. But when the mask sheet is extended with tension in each direction to prevent the mask sheet from sagging, a pitch of each opening in the mask sheet may be distorted.

### SUMMARY OF THE INVENTION

The present invention provides a deposition mask capable of preventing a mask sheet from bending and a method of manufacturing the same.

Additional features of the invention will be set forth in the description which follows, and in part will be apparent from the description, or may be learned by practice of the invention.

The present invention discloses a mask for depositing a layer including a mask sheet, supporting frame, and mask frame. The mask sheet includes at least two openings with different sizes from each other and a blocking part disposed in a region where the at least two openings are not formed. The supporting frame is disposed on a back side of the mask sheet to support the mask sheet, and the mask frame receives a peripheral region of the supporting frame and supports a vertical pressure applied to the supporting frame and the mask sheet.

The present invention also discloses a method of manufacturing a deposition mask including preparing a mask sheet having a blocking part defining a plurality of openings with different sizes from each other, a supporting frame corresponding to the blocking part, and a mask frame. The edge of the supporting frame is attached to the mask frame, and the blocking part is attached to the supporting frame.

The present invention also discloses a method of manufacturing an organic electroluminescent display device including forming a thin film transistor on a substrate including at least two display elements with different sizes from each other, forming a first electrode connected to the thin film transistor, forming a bank insulation layer exposing the first electrode, aligning a deposition mask with the substrate, depositing an organic material on the display area of the substrate to form an organic layer, and forming a second electrode on the organic layer. The deposition mask includes a mask sheet having openings respectively exposing at least a portion of the at least two display elements, a supporting frame supporting the mask sheet, and a mask frame supporting the mask sheet. The openings of the mask correspond to a display area of the display elements.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1 is a plan view showing an organic electroluminescent (“EL”) display device.

FIG. 2 is a cross-sectional view taken along line I-I′ of FIG. 1.

FIG. 3A, FIG. 3B, FIG. 3C, FIG. 3D, FIG. 3E, FIG. 3F, FIG. 3G, FIG. 3H, and FIG. 3I are cross-sectional views showing a method of manufacturing an organic EL display device according to an exemplary embodiment of the present invention.

FIG. 4 is a cross-sectional view showing an organic layer deposition device for forming an organic layer using a deposition mask according to an exemplary embodiment of the present invention.

FIG. 5A and FIG. 5B are a perspective view and a cross-sectional view, respectively, showing a deposition mask according to an exemplary embodiment of the present invention.

FIG. 6A is a view showing a method of manufacturing a deposition mask according to a first exemplary embodiment of the present invention.

FIG. 6B is a view showing a method of manufacturing a deposition mask according to a second exemplary embodiment of the present invention.

FIG. 6C is a view showing a method of manufacturing a deposition mask according to a third exemplary embodiment of the present invention.

FIG. 7 is a view showing a method of manufacturing a deposition mask according to a fourth exemplary embodiment of the present invention.

### DETAILED DESCRIPTION OF THE ILLUSTRATED EMBODIMENTS

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure is thorough, and will fully convey the scope of the invention to those skilled in the art. In the drawings, the size and relative sizes of layers and regions may be exaggerated for clarity. Like reference numerals in the drawings denote like elements.

It will be understood that when an element such as a layer, film, region or substrate is referred to as being “on” or “connected to” another element, it can be directly on or directly connected to the other element or intervening elements may also be present. In contrast, when an element is referred to as being “directly on” or “directly connected to” another element, there are no intervening elements present.

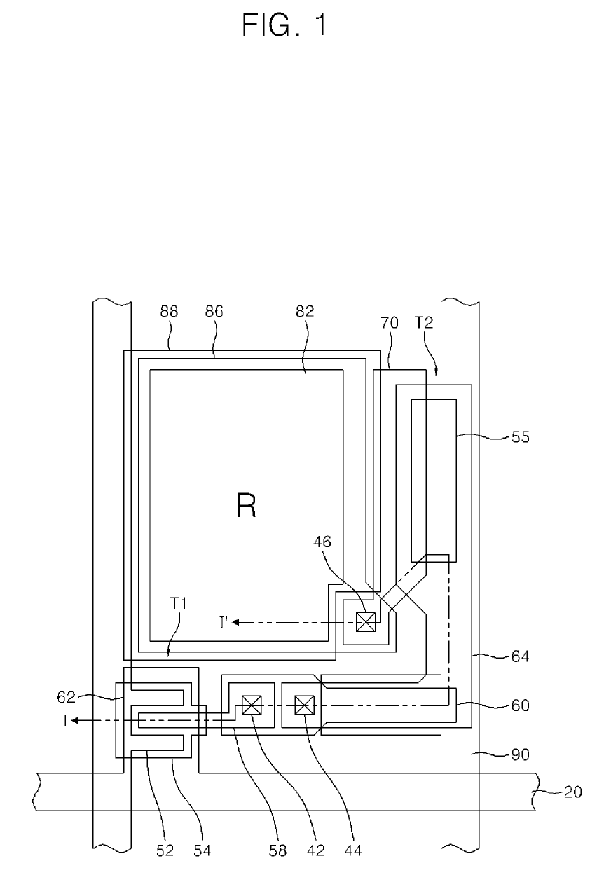

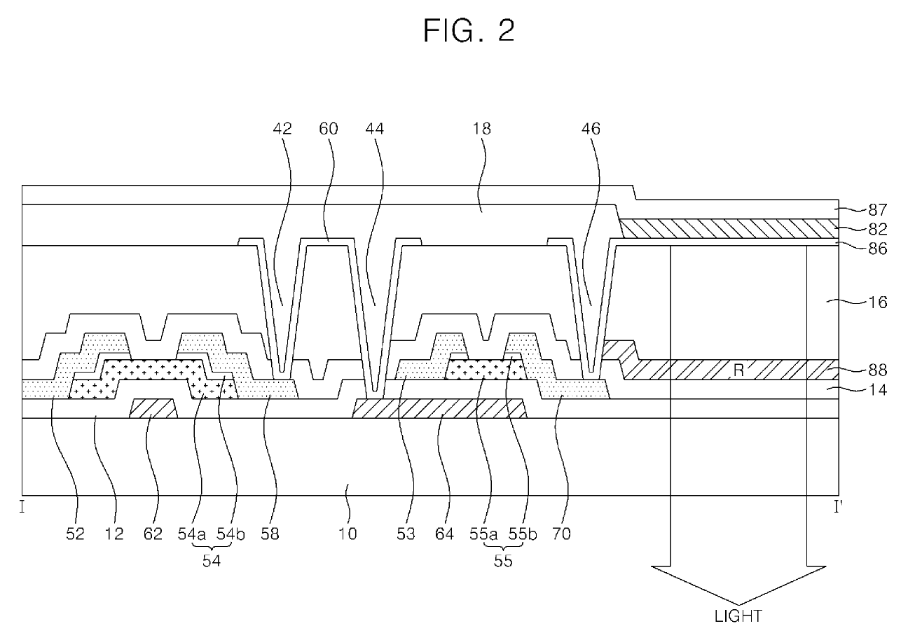

FIG. 1 is a plan view showing an EL display device, and FIG. 2 is a cross-sectional view taken along line I-I′ of FIG. 1.

In the organic EL display device according to an exemplary embodiment of the present invention, a pixel includes red (“R”), green (“G”), blue (“B”) and white (“W”) sub-pixels. Each pixel formed in a 2×2 matrix constitutes a unit pixel. The unit pixels are repeatedly formed in columns and rows. The R, G, B, and W sub-pixels may have the same structure except for their colors. Accordingly, only a structure of the R sub-pixel will be described below by way of example.

Referring to FIG. 1 and FIG. 2, the organic EL display device includes a gate line 20 formed on an insulation substrate 10, a data line 30 insulated from and crossing the gate line 20, a power line 90 insulated from and crossing the gate line 20 and formed parallel to the data line 30, a switching thin film transistor (“switching TFT”) T1 connected to the gate line 20 and the data line 30, a driving thin film transistor (“driving TFT”) T2 connected to the switching TFT T1 and the power line 90, a storage capacitor connected between the power line 90 and a first drain electrode 58 of the switching TFT T1, and a color filter 88 overlapping an organic EL cell.

The gate line 20 supplies a scan signal to the switching TFT T1, the data line 30 supplies a data signal to the switching TFT T1, and the power line 90 supplies a power signal to the driving TFT T2.

The switching TFT T1 turns on when receiving a scan signal from the gate line 20, thereby supplying the data signal from the data line 30 to the storage capacitor and a second gate electrode 64 of the driving TFT T2.

The switching TFT T1 includes a first gate electrode 62 connected to the gate line 20, a first source electrode 52 connected to the data line 30, a first drain electrode 58 facing the first source electrode 52 and connected to the second gate electrode 64 of the driving TFT T2, and a first semiconductor pattern 54, which forms a channel region between the first source electrode 52 and the first drain electrode 58. The first semiconductor pattern 54 includes a first active layer 54a overlapping the first gate electrode 62 with a gate insulation layer 12 disposed therebetween, and a first ohmic contact layer 54b formed on the first active layer 54a except for the channel region for ohmic contact with the first source electrode 52 and the first drain electrode 58.

The driving TFT T2 controls luminescence of the organic EL cell by controlling the current provided to the organic EL cell from the power line 90 in response to the data signal supplied to the second gate electrode 64. The driving TFT T2 includes the second gate electrode 64, which is connected to the first drain electrode 58 of the switching TFT T1 through a connection electrode 60, a second source electrode 53 connected to the power line 90, a second drain electrode 70 facing the second source electrode 53 and connected to the first electrode 86 of the organic EL cell, and a second semiconductor pattern 55, which forms a channel region between the second source and drain electrodes 53 and 70. The connection electrode 60 may be formed of the same material as the first electrode 86 and on the same layer as the first electrode 86 (e.g., on a planarization layer 16). The connection electrode 60 connects the first drain electrode 58 of the switching TFT T1, which is exposed by a first contact hole 42, to the second gate electrode 64 of the driving TFT T2, which is exposed by a second contact hole 44. The first contact hole 42 penetrates a protection layer 14 and the planarization layer 16 to expose the first drain electrode 58. The second contact hole 44 penetrates the gate insulation layer 12, the protection layer 14, and the planarization layer 16 to expose the second gate electrode 64. The second semiconductor pattern 55 includes a second active layer 55a overlapping the second gate electrode 64 with the gate insulation layer 12 disposed therebetween, and a second ohmic contact layer 55b formed on the second active layer 55a except for the channel region for ohmic contact with the second source electrode 53 and the second drain electrode 70.

The storage capacitor is formed by the power line 90 overlapping the second gate electrode 64 of the driving TFT T2 with the gate insulation layer 12 disposed therebetween. Although the switching TFT T1 is turned off, a voltage charged in the storage capacitor enables the driving TFT T2 to maintain the luminescence of the organic EL cell until a data signal in a subsequent frame is provided.

A second electrode 87 faces the first electrode 86, and an organic layer 82, which is formed in a sub-pixel unit, is disposed between the second and first electrodes 87 and 86. The first electrode 86 is separately formed on the planarization layer 16 in each sub-pixel area to overlap the color filter 88. The first electrode 86 is connected to the second drain electrode 70 of the driving TFT T2 via the third contact hole 46, which penetrates the protection layer 14 and the planarization layer 16.

The color filter 88 is formed on the protection layer 14 and overlaps the organic layer 82, which generates W light. Accordingly, the color filters 88 in the sub-pixels generate R, G and B light using the W light generated from the organic layer 82. The R, G and B light generated from the color filters 88 is emitted through the insulation substrate 10.

The organic EL cell includes the first electrode 86, which is made of a transparent conductive material, the organic layer 82, which includes a light emitting layer formed on the first electrode 86 and a bank insulation layer 18, and the second electrode 87, which is formed on the organic layer 82. The organic layer 82 may include a hole injection layer, a hole transport layer, a light emitting layer, an electron transport layer, and an electron injection layer, which are formed on the first electrode 86 and the bank insulation layer 18. The light emitting layer may be implemented in the form of a triple color layer that emits R, G and B light, respectively. The light emitting layer may also be implemented in the form of a dual layer that emits complementary colors or in the form of a single layer that emits W light. According to the exemplary embodiment of FIG. 2, the light emitting layer in the organic layer 82 generates light according to the amount of current supplied to the first electrode 86 and emits W light toward the color filter 88 through the first electrode 86.

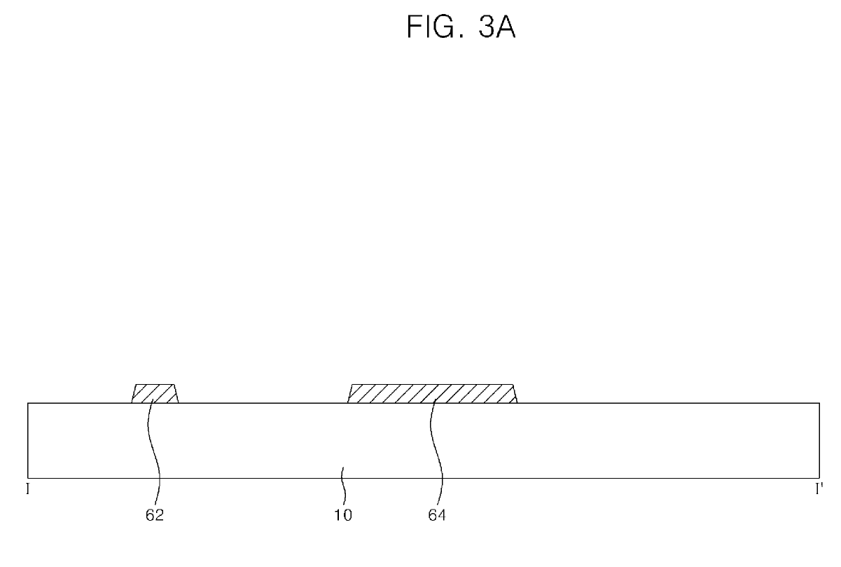

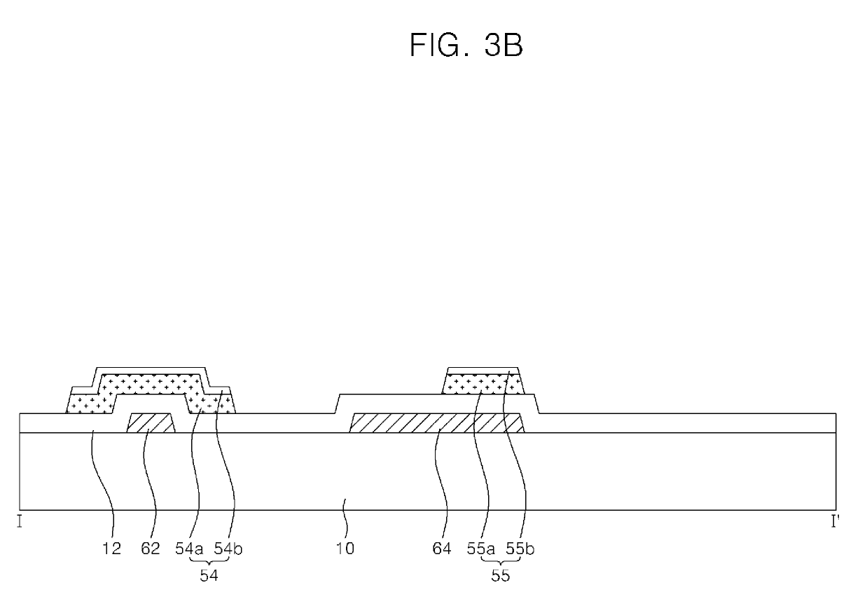

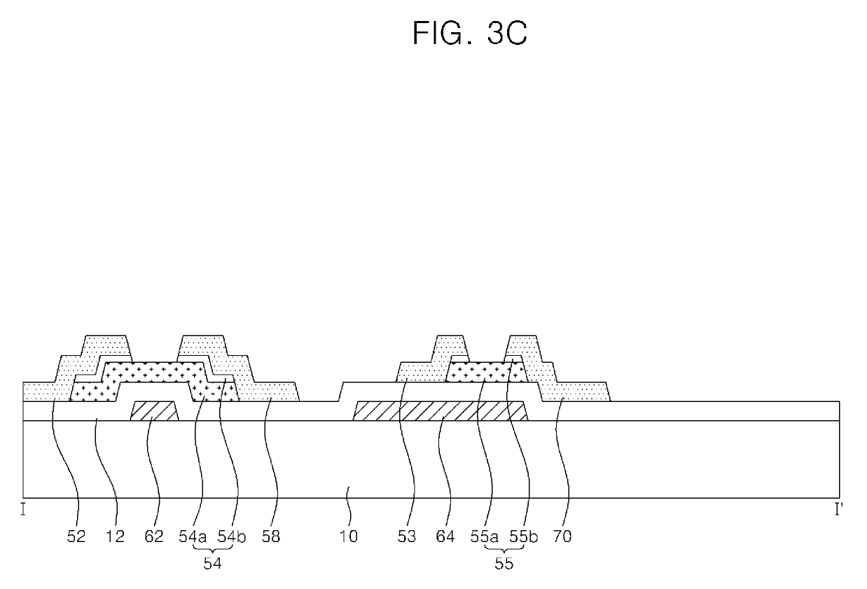

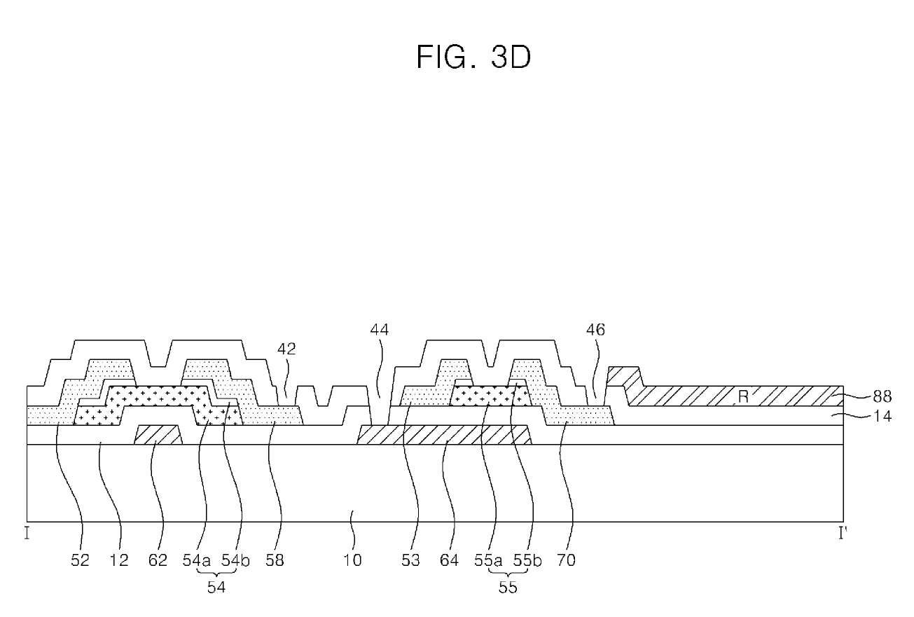

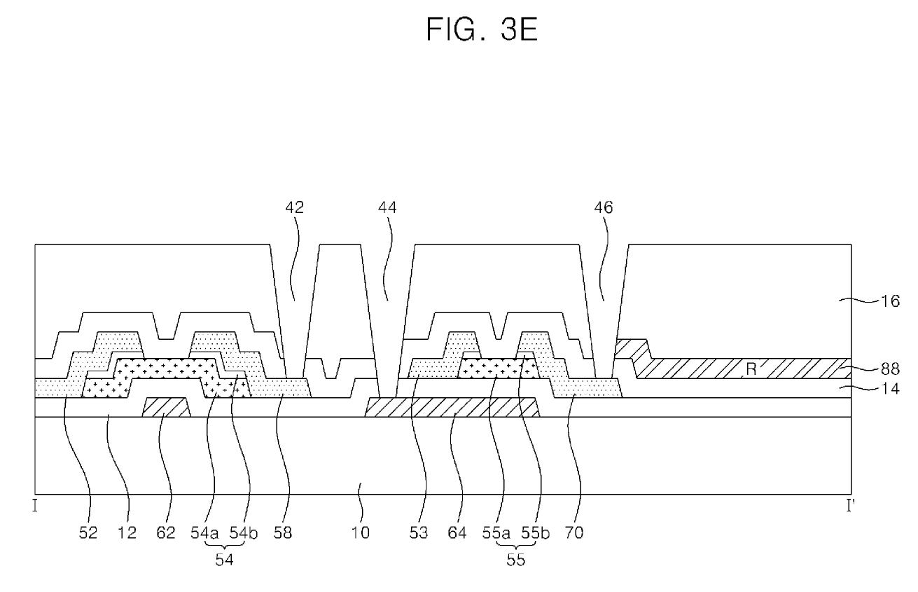

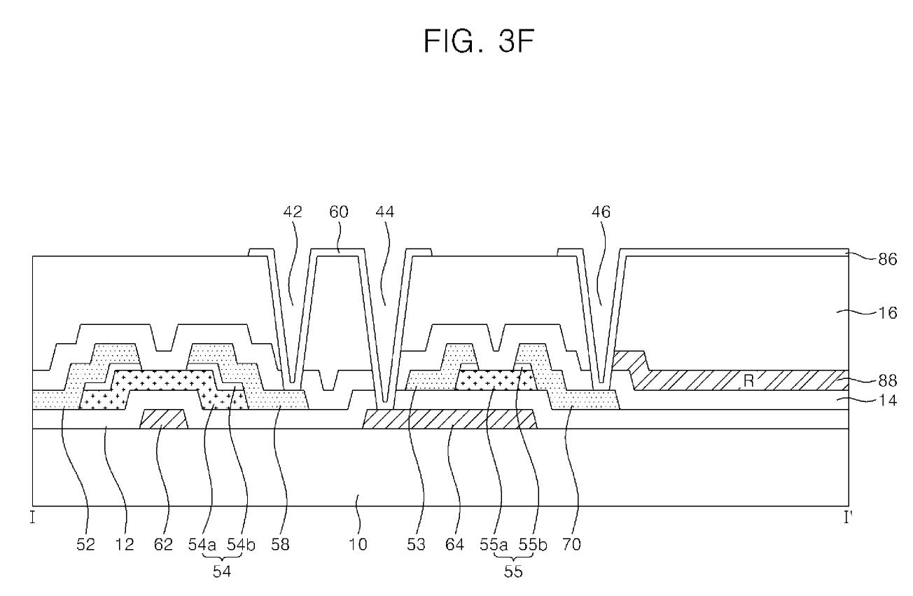

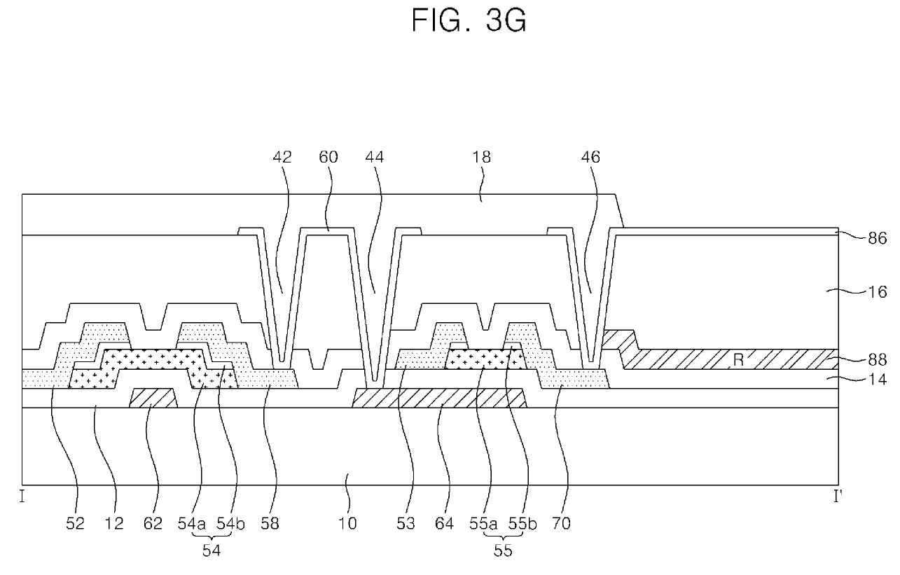

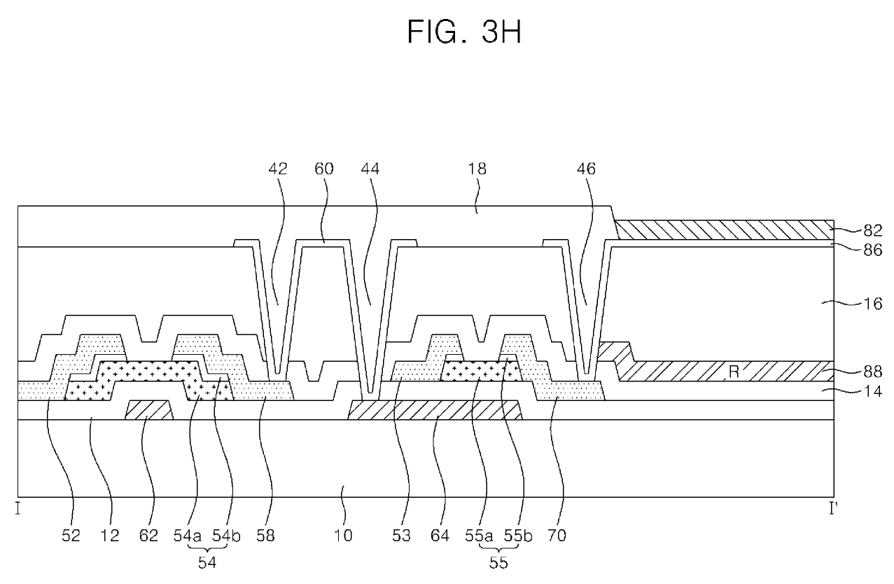

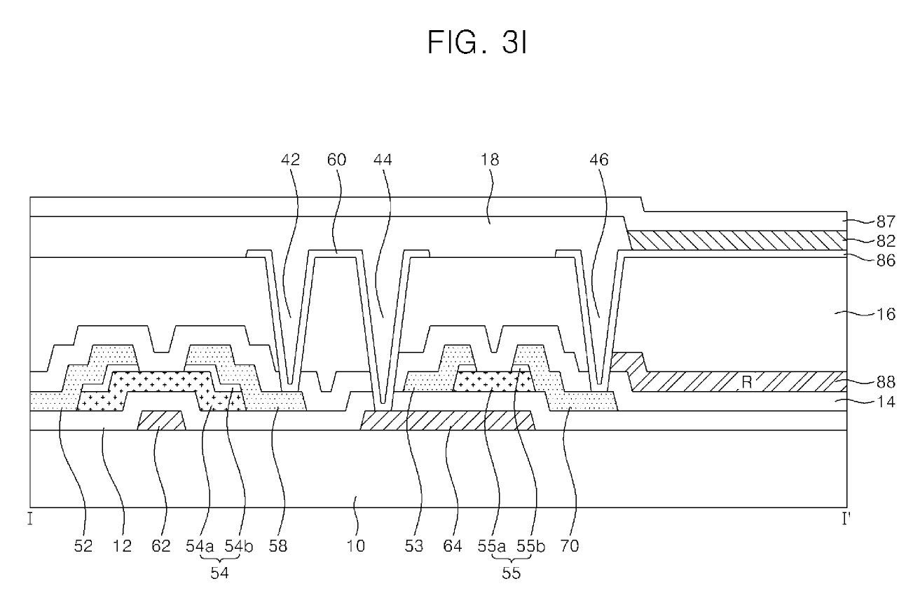

FIG. 3A, FIG. 3B, FIG. 3C, FIG. 3D, FIG. 3E, FIG. 3F, FIG. 3G, FIG. 3H, and FIG. 3I are cross-sectional views showing a method of manufacturing an organic EL display device according to an exemplary embodiment of the present invention.

Referring to FIG. 3A, a gate metal pattern including the gate line 20 and the first and second gate electrodes 62 and 64 is formed on the insulation substrate 10.

More specifically, a gate metal layer may be formed on the insulation substrate 10 by a deposition method such as sputtering. Thereafter, the gate metal layer is patterned by photolithography and etching processes to form the gate metal pattern.

Referring to FIG. 3B, the gate insulation layer 12 is formed on the insulation substrate 10 having the gate metal pattern. Then a first semiconductor pattern 54, which includes a first active layer 54a and a first ohmic contact layer 54b, and a second semiconductor pattern 55, which includes a second active layer 55a and a second ohmic contact layer 55b, are formed on the gate insulating layer 12.

The gate insulation layer 12 may be formed on the insulation substrate 10 including the gate metal pattern by depositing an inorganic insulation material such as silicon oxide (SiOx) or silicon nitride (SiNx) using a deposition method such as plasma enhanced chemical vapour deposition (“PECVD”). The first and second semiconductor patterns 54 and 55 may be formed by forming an amorphous silicon layer and n+ amorphous silicon layer and then patterning the amorphous silicon layer and the n+ amorphous silicon layer using photolithography and etching processes.

Referring to FIG. 3C, a first source/drain metal pattern including the data line 30, the first source electrode 52, and the first drain electrode 58 and a second source/drain metal pattern including the power line 90, the second source electrode 53, and the second drain electrode 70 are formed on the insulation substrate 10 having the semiconductor patterns 54 and 55.

The source/drain metal patterns may be formed by depositing source/drain metal layers on the insulation layer 10 by, for example, a sputtering process after forming the first and second semiconductor patterns 54 and 55, and then patterning the source/drain metal layers using photolithography and etching processes. Thereafter, by using the first source and drain electrodes 52 and 58 and the second source and drain electrodes 53 and 70 as masks, portions of the first and the second ohmic contact layers 54b and 55b exposed therebetween may be removed, thereby exposing the first and second active layers 54a and 55a.

Referring to FIG. 3D, the protection layer 14 is formed on the insulation substrate 10 having the source/drain metal patterns. A red color filter 88 is formed on the protection layer 14.

The protection layer 14 may be formed by depositing an inorganic insulation material such as SiOx or SiNx or an organic insulation material such as an acryl resin on the insulation substrate 10 including the source/drain metal patterns. The red color filter 88 may be formed by depositing a red pigment material on the insulation substrate 10 including the protection layer 14 and then patterning the red pigment material using a photolithography process.

Referring to FIG. 3E, the planarization layer 16 including the first, second, and third contact holes 42, 44 and 46 is formed on the insulation substrate 10 having the protection layer 14 and the color filter 88.

The planarization layer 16 may be formed through a spin coating method or a spinless coating method. The first, second, and third contact holes 42, 44, and 46 are formed by selectively patterning at least one of the gate insulation layer 12 and the protection layer 14 using photolithography and etch processes. The first contact hole 42 penetrates the protection layer 14 and the planarization layer 16 to expose the first drain electrode 58 of the switching TFT T1. The second contact hole 44 penetrates the gate insulation layer 12, the protection layer 14, and the planarization layer 16 to expose the second gate electrode 64 of the driving TFT T2. The third contact hole 46 penetrates the protection layer 14 and the planarization layer 16 to expose the second drain electrode 70 of the driving TFT T2.

Referring to FIG. 3F, a transparent conductive pattern including a connection electrode 60 and the first electrode 86 is formed on the insulation substrate 10 having the planarization layer 16.

The transparent conductive pattern may be formed by depositing a transparent conductive layer on the planarization layer 16 using a deposition technique such as sputtering and then patterning the transparent conductive layer through photolithography and etching processes. The transparent conductive layer may be made of a transparent conductive material such as indium tin oxide (ITO), tin oxide (TO), indium zinc oxide (IZO), or indium tin zinc oxide (ITZO).

Referring to FIG. 3G, the bank insulation layer 18 is formed on the insulation substrate 10 having the connection electrode 60 and the first electrode 86.

The bank insulation layer 18 may be formed by depositing an organic insulation material on the insulation substrate 10 and then patterning the organic insulation material using photolithography and etching processes.

Referring to FIG. 3H, the organic layer 82 is formed on the insulation substrate 10 having the bank insulation layer 18.

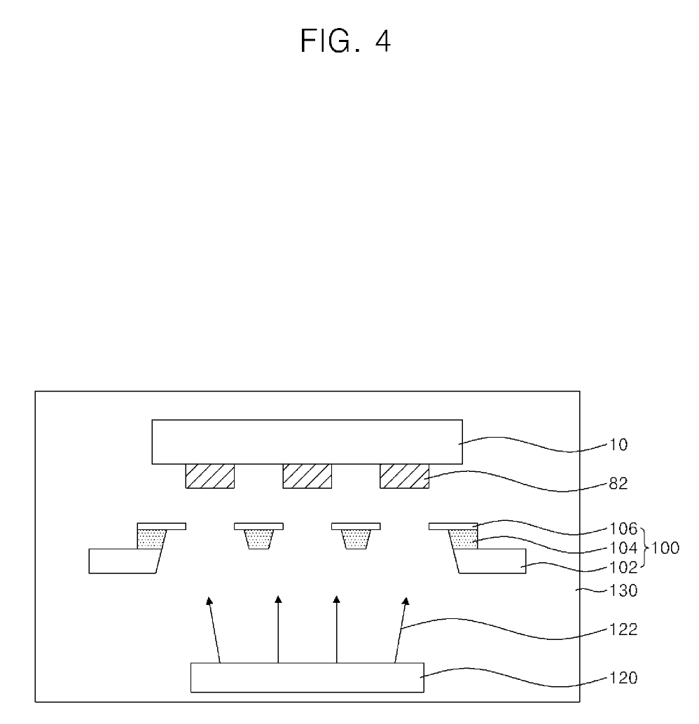

The organic layer 82 may be formed within a chamber using a deposition process. The light emitting layer included in the organic layer 82 may be implemented with sequentially deposited R, G, and B emission layers or two color layers having complementary relationship. Also, the organic layer 82 may be implemented as a single color layer that emits W light. The organic layer 82 may be formed using a deposition mask having at least two openings of different sizes and a supporting frame. Thus, a shadow phenomenon may be prevented and a desired pattern may be obtained, thereby improving the panel characteristics. A method of forming the organic layer according to an exemplary embodiment of the present invention will be described below with reference to FIG. 4.

Referring to FIG. 3I, the second electrode 87 is formed on the insulation substrate 10 having the organic layer 82.

The second electrode 87 may be formed by depositing a metal on the insulation substrate 10 having the organic layer 82. The second electrode 87 may be made of metal having high reflectivity such as Al, Mg, Ag, Ca or MaAg.

FIG. 4 is a cross-sectional view showing an organic layer deposition device for forming an organic layer using a deposition mask according to an exemplary embodiment of the present invention.

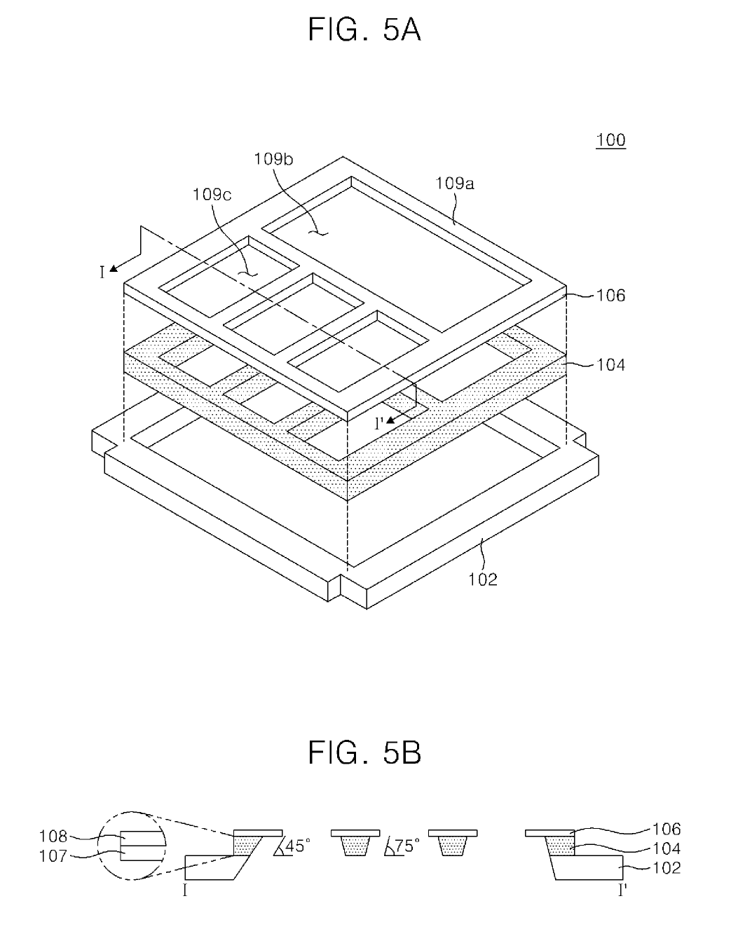

As described below with reference to FIG. 5A, the deposition mask 100 for forming the organic layer 82 may include one large-sized opening and three middle-sized openings. The large-sized opening and middle-sized openings correspond to panels having different sizes.

The organic layer deposition device for forming the organic layer 82 includes a vacuum chamber 130, a deposition source 120 providing an organic material, and the deposition mask 100, which includes a mask sheet 106, a mask frame 102, and a supporting frame 104. The insulation substrate 10, on which the organic layer 82 is to be deposited, is arranged in the vacuum chamber 130.

The insulation substrate 10 is a substrate for forming an organic EL display device thereon. An organic material provided from the deposition source 120 may be sequentially stacked on the insulation substrate 10. For example, organic materials including a hole injection layer, a hole transport layer, a light emitting layer, an electron transport layer, and an electron injection layer may be sequentially stacked using the mask sheet 106 having a large-sized opening and a small-sized opening. The light emitting layer may be implemented with a three-layer structure having light emitting layers that emit R, G and B light, respectively, a two-layer structure in which light emitting layers emit complementary colors, or a single layer structure that emits W light. The insulation substrate 10 may be made of glass such as soda lime glass.

The deposition source 120 provides an organic vapour 122, which is deposited on the insulation substrate 10, in the vacuum chamber 130. The deposition source 120 contains an organic material to be deposited on the insulation substrate 10 and heats the organic material to change it into a gas. The evaporated and sublimed organic material may then be deposited on the insulation substrate 10. The number and shape of the deposition sources 120 may change and may be formed in the vacuum chamber 130.

The deposition mask 100 is a guiding component to deposit the organic material supplied from the deposition source 120 on the insulation substrate 10 as desired. The deposition mask 100 is closely attached to the insulation substrate 10. The deposition mask 100 includes the mask sheet 106, the mask frame 102, and the supporting frame 104. The mask sheet 106 includes at least two openings with different sizes and a blocking part formed in a region without the openings. The mask frame 102 supports the vertical pressure and includes openings corresponding to the openings of the mask sheet 106, and the supporting frame 104 supports the mask sheet 106. The deposition mask 100 according to an exemplary embodiment of the present invention will now be described in detail with reference to FIG. 5A and FIG. 5B.

Referring to FIG. 5A and FIG. 5B, the mask sheet 106 is aligned on the insulation substrate 10 such that a surface to which the organic vapour is deposited corresponds to the deposition source, and includes a large-sized opening 109b, middle-sized openings 109c, and a blocking part 109a. The large-sized opening 109b of the mask sheet 106 corresponds to a display area of a large-sized panel of more than about 30 inches, and the middle-sized openings 109c correspond to a display area of a middle-sized panel of about 5 to 10 inches. The blocking part 109a blocks an area on which the large-sized and middle-sized openings 109b and 109c of the mask sheet 106 are not formed. The thickness of the mask sheet 106 permits a shadow phenomenon to some degree and may be about 0.1 mm to about 0.2 mm to improve the bending and handling of the mask sheet 106. The mask sheet 106 may be made of a metal such as stainless steel.

The mask frame 102 supports a vertical load and peripheral region of the supporting frame 104 and the mask sheet 106. The mask frame 102 has a rectangular shape with a cavity in the middle portion. The mask frame 102 may prevent a shadow phenomenon of the organic vapour since the mask frame 102 is linearly formed along a taper angle of the supporting frame 104. The mask frame 102 may be made of, for example, a lightweight metal such as Al. The mask frame 102 may be made of single or multiple layers.

The supporting frame 104 is positioned between the mask frame 102 and the mask sheet 106 to prevent the mask sheet 106 from sagging. The supporting frame 104 guides a path of the organic vapour 122, which is to be deposited on the insulation substrate 10. The supporting frame 104 includes openings corresponding to the openings 109b and 109c and a blocking part corresponding to the blocking part 109a of the mask sheet 106.

The openings of the supporting frame 104 are larger than the openings 109b and 109c of the mask sheet 106 such that the openings of the supporting frame 104 are not visible when viewing the mask 100 in plan view. In other words, the shadow phenomenon may be when an organic material is disposed as the supporting frame 104 is formed smaller than the mask sheet 106.

As shown in FIG. 5B, the shadow phenomenon may be reduced when the supporting frame 104 contacting the mask frame 102 has a taper angle of less than about 45 degrees, and the supporting frame 104 overlapping the blocking part 109a of the mask sheet 106 has a taper angle of less than about 75 degrees.

The upper portion of the supporting frame 104 overlapping the mask sheet 106 may be formed of a first conductive layer 108, which includes a metal such as Fe—Cr, Fe—Ni alloy (for example, Fe-36% Ni alloy), or Ti.

The lower portion of the supporting frame 104 overlapping the mask frame 102 may be formed of a second conductive layer 107, which includes a lightweight metal such as Al.

The first conductive layer 108 may be formed less than about 1 mm thick, for example, about 0.1 to about 0.2 mm thick, such that the first conductive layer 108 may be easily attached to the mask sheet 106 and prevent the sagging problem. Although the supporting frame 104 formed with a double structure is shown, the supporting frame 104 may have a multi-layer structure using multiple layers between the first and the second conductive layers 107 and 108.

According to an exemplary embodiment of the present invention, the deposition mask 100 includes the supporting frame 104 having a taper angle such that the shadow phenomenon may be prevented when organic vapour is deposited on the insulation substrate 10 and the sagging problem may be prevented by supporting the mask sheet 106.

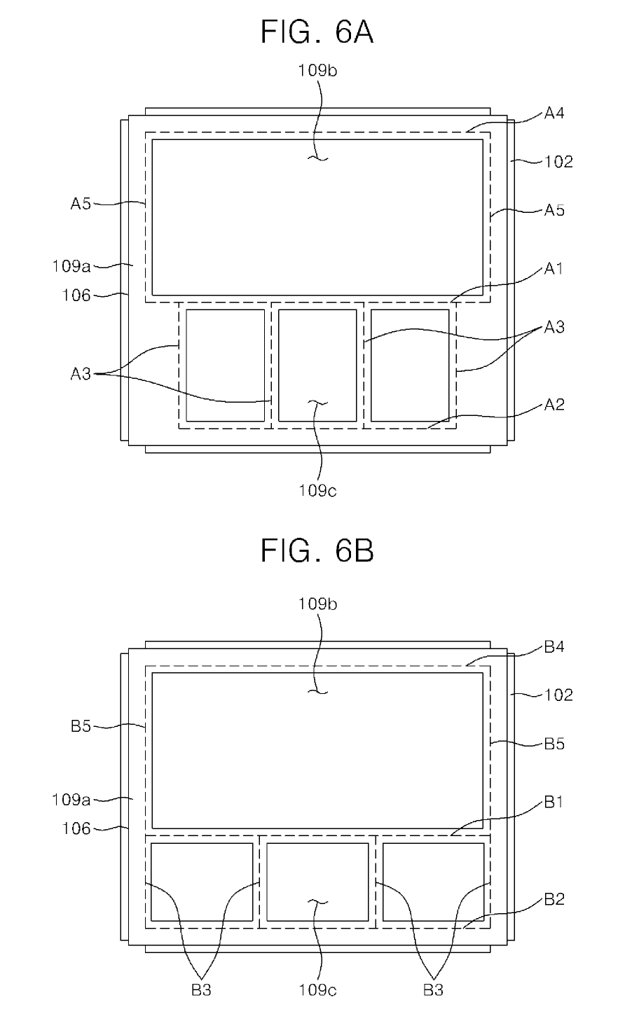

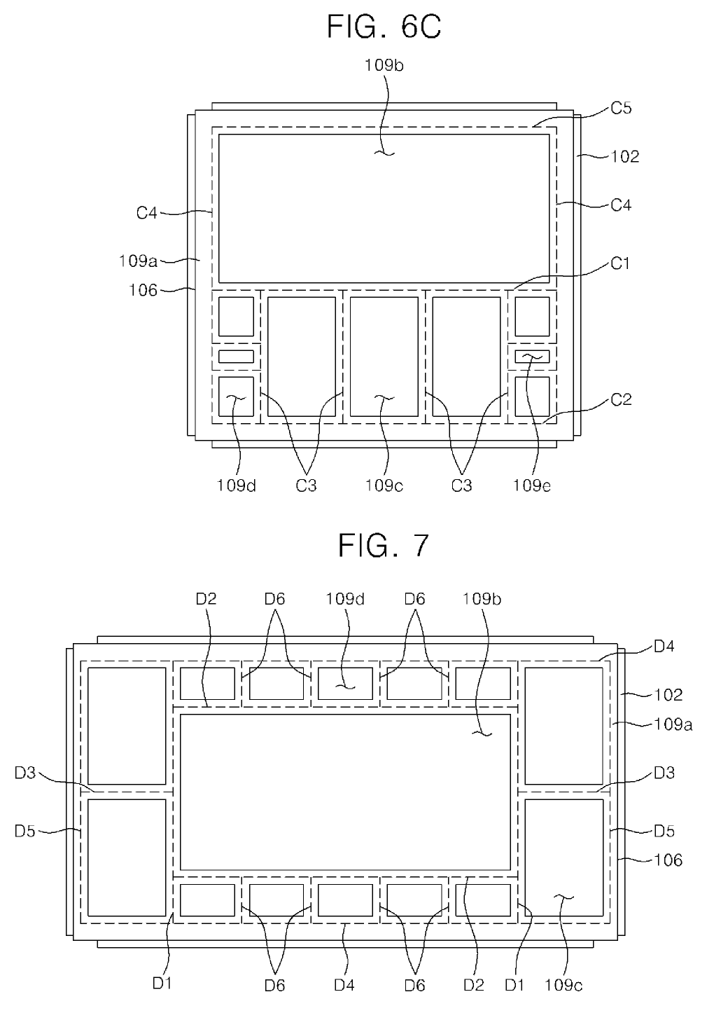

According to an exemplary embodiment of the present invention, the attaching sequence of the mask sheet 106 to the supporting frame 104 is important to prevent the deposition mask 100 from sagging. In particular, the blocking part 109a formed between the middle-sized openings may have the most serious sagging problem. FIG. 6A shows a method of manufacturing the deposition mask 100 by separately arraying a large-sized panel and vertically arranged middle-sized panels.

Referring to FIG. 5A and FIG. 6A, the supporting frame 104 is mounted on the mask frame 102 to be aligned with the insulation substrate 10. Then, the mask sheet 106 is mounted on the supporting frame 104 to be aligned with the insulation substrate 10. The mask sheet 106 includes the large-sized opening 109b having a display area size of the large-sized panel in a transverse direction, a plurality of middle-sized openings 109c having a display area size of the middle-sized panel, and the blocking part 109a.

The attachment sequence is as follows. A blocking part Al, which is formed in a transverse direction between the large-sized and middle-sized openings 109b and 109c, is extended and attached to the supporting frame 104 shown in FIG. 5A. Then, a blocking part A2, which is formed in a transverse direction at the outermost side of the mask sheet 106 and adjacent to the middle-sized openings 109c, is extended and attached to the mask frame 104. Then, blocking parts A3, which are formed in a vertical direction at both sides of the middle-sized openings 109c, are extended and attached to the mask frame 104. Then, a blocking part A4, which is formed in a transverse direction at the outermost side of the mask sheet 106 and adjacent to the large-sized opening 109b, is extended and attached to the supporting frame 104. Finally, blocking parts A5, which are formed in a vertical direction at both sides of the large-sized opening 109b, are extended and attached to the supporting frame 104.

FIG. 6B is a view for showing a method of manufacturing a deposition mask according to a second exemplary embodiment of the present invention.

FIG. 6B shows the deposition mask 100 including a large-sized panel and middle-sized panels arranged in a transverse direction.

Referring to FIG. 6B, the mask sheet 106 includes the large-sized opening 109b corresponding to a large-sized panel display area, the plurality of middle-sized openings 109c corresponding to a middle-sized panel display area, and the blocking part 109a. The middle-sized openings 109c are horizontally arranged.

The attachment sequence is as follows. A blocking part B1, which is formed in a transverse direction between the large-sized and middle-sized openings 109b and 109c, is extended and attached to the supporting frame 104 shown in FIG. 5A. Then, a blocking part B2, which is formed in a transverse direction at the outermost side of the mask sheet 106 and adjacent to the middle-sized opening 109c, is extended and attached to the mask frame 104. Then, blocking parts B3, which are formed in a vertical direction at both sides of the middle-sized openings 109c, are extended and attached to the mask frame 104. Then, a blocking part B4, which is formed in a transverse direction at the outermost side of the mask sheet 106 and adjacent to the large-sized opening 109b, is extended and attached to the supporting frame 104. Finally, blocking parts B5, which are formed in a vertical direction at both sides of the large-sized opening 109b, are extended and attached to the supporting frame 104.

FIG. 6C is a view for showing a method of manufacturing a deposition mask according to a third exemplary embodiment of the present invention.

FIG. 6C describes an arrangement of the deposition mask 100 having a large-sized, middle-sized, and small-sized panels.

Referring to FIG. 6C, the mask sheet 106 includes the large-sized opening 109b corresponding to the size of a display area of the large-sized panel, the plurality of middle-sized openings 109c corresponding to the size of a display area of the middle-sized panel, middle/small-sized openings 109d positioned next to the middle-sized openings 109c, small-sized openings 109e positioned between the middle/small-sized openings 109d, and the blocking part 109a blocking a part other than the above openings.

The attachment sequence is as follows. A blocking part C1, which is formed in a transverse direction between the large-sized and middle-sized openings 109b and 109c, is extended and attached to the supporting frame 104 shown in FIG. 5A. Then, a blocking part C2, which is formed in a transverse direction at the outermost side of the mask sheet 106 and adjacent to the middle-sized openings 109c, is extended and attached to the mask frame 104. Then, blocking parts C3, which are formed in a vertical direction at both sides of the middle-sized openings 109c, are extended and attached to the mask frame 104. Then, blocking parts C4, which are formed in a vertical direction at both sides of the mask sheet 106, are extended and attached to the supporting frame 104. Finally, a blocking part C5, which is formed in a transverse direction at the outermost side of the mask sheet 106 and adjacent to the large-sized opening 109b, is extended and attached to the supporting frame 104.

The deposition masks 100 in FIG. 6A, FIG. 6B, and FIG. 6C include a large-sized opening 109b formed in one area and middle- and small-sized openings 109c, 109d, and 109e formed in the other areas. The blocking part 109a between the large-sized and middle-sized openings is attached to the supporting frame 104 and then the blocking parts 109a between the middle-sized openings are attached to the supporting frame 104. Thereafter, the blocking part formed at the outer side of the large-sized opening is attached to the supporting frame 104. A method of forming the deposition mask 100 having the large-, middle- and small-sized openings according to an exemplary embodiment of the present invention may prevent the mask sheet 106 from bending downwardly.

FIG. 7 is a view for showing a method of manufacturing a deposition mask according to a fourth exemplary embodiment of the present invention. The deposition mask 100 includes a large-sized opening, middle-sized openings, and middle/small-sized openings surrounding the large-sized opening.

Referring to FIG. 7, the mask sheet 106 includes the large-sized opening 109b, the plurality of middle-sized openings 109c, the plurality of middle/small-sized openings 109d, and the blocking area 109a.

The attachment sequence is as follows. Blocking parts D1, which are formed in a vertical direction between the large-sized opening 109b and the middle-sized openings 109c, are extended and attached to the supporting frame 104. Then, blocking parts D2, which are formed in a transverse direction between the large-sized opening 109b and the middle/small-sized openings 109d, are extended and attached to the supporting frame 104. Blocking parts D3, which are formed in a transverse direction between the middle-sized openings 109c, are extended and attached to the supporting frame 104. Thereafter, blocking parts D4 formed in a transverse direction and blocking parts D5 formed in a vertical direction at the outermost sides of the mask sheet 106 are extended to be attached to the supporting frame 104. Next, the blocking parts D6, which are formed in a vertical direction, are extended and attached to the supporting frame 104.

The sequence of attachment according to an exemplary embodiment of the present invention varies according to the locations of the large opening. Thus, the mask sheet 106 can be prevented from bending downwardly. In addition, wrinkles, which deteriorate the characteristics of the panel, may not occur in the peripheral area of the mask sheet 106.

The deposition mask 100 according to an exemplary embodiment of the present invention may be used in any display device manufactured through a deposition process.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

What is claimed is:

1. A mask for depositing a layer, comprising:
a mask sheet comprising at least two openings with different sizes from each other and a blocking part disposed in a region where the at least two openings are not formed;
a supporting frame disposed on a back side of the mask sheet to support the mask sheet; and
a mask frame to receive a peripheral region of the supporting frame and to support a vertical pressure applied to the supporting frame and the mask sheet.

2. The mask of claim 1, wherein the supporting frame comprises openings corresponding to the at least two openings of the mask sheet.

3. The mask of claim 1, wherein the mask frame comprises a multi-layer structure.

4. The mask of claim 3, wherein the supporting frame comprises a first conductive layer and a second conductive layer.

5. The mask of claim 4, wherein the first conductive layer comprises one of a Fe—Cr alloy, a Fe—Ni alloy, and T1, and the second conductive layer comprises Al.

6. The mask of claim 5, wherein a thickness of the first conductive layer is about 0.1 mm to about 1 mm.

7. The mask of claim 3, wherein the supporting frame has a first taper angle and a second taper angle, the first taper angle in a region overlapping the mask frame being less than about 45 degrees, and the second taper angle in a region overlapping the blocking part being less than about 75 degrees.

8. A method of manufacturing a deposition mask, comprising:
preparing a mask sheet having a blocking part defining a plurality of openings with different sizes from each other, a supporting frame corresponding to the blocking part, and a mask frame;
attaching an edge of the supporting frame to the mask frame; and
attaching the blocking part to the supporting frame.

9. The method of claim 8, wherein the openings comprise a large-sized opening and a plurality of middle-sized openings arranged parallel to each other in a transverse direction at a lower side of the large-sized opening, and wherein attaching the blocking part to the supporting frame comprises:
extending the mask sheet in an arrangement direction of the middle-sized openings and attaching the blocking part between the middle-sized openings and the large-sized opening to the supporting frame;
attaching the blocking part at a lower side of the middle-sized openings to the supporting frame;
attaching the blocking part between the middle-sized openings to the supporting frame; and
attaching the blocking part at an upper side of the large-sized opening to the supporting frame.

10. The method of claim 9, further comprising:
attaching the blocking part in a vertical direction of an edge of the mask sheet adjacent to the outermost ones of the middle-sized openings; and
attaching the blocking part in a vertical direction of the edge of the mask sheet adjacent to the large-sized opening to the supporting frame;
wherein when a vertical boundary of the outermost ones of the middle-sized openings is identical to a vertical boundary of the large-sized opening, the blocking part in the vertical direction of the mask sheet adjacent to the outermost ones of the middle-sized openings and the blocking part in the vertical direction of the mask sheet adjacent to the large-sized opening are simultaneously attached before attaching the blocking part at the upper side of the large-sized opening.

11. The method of claim 9, further comprising:
attaching the blocking part in a vertical direction of an edge of the mask sheet adjacent to the outermost ones of the middle-sized openings; and
attaching the blocking part in a vertical direction of the edge of the mask sheet adjacent to the large-sized opening to the supporting frame;
wherein when a vertical boundary of the outermost ones of the middle-sized openings is not identical to a vertical boundary of the large-sized opening, the blocking part in the vertical direction of the mask sheet adjacent to the outermost ones of the middle-sized openings is attached together with the blocking part in the vertical direction between the middle-sized openings.

12. The method of claim 8, wherein the openings comprise a large-sized opening, a plurality of small-sized openings vertically arranged at lower sides of edges of both sides of the large-sized opening, and a plurality of middle-sized openings transversely arranged parallel to each other at a lower side of the large-sized opening, and wherein attaching the blocking part to the supporting frame comprises:
extending the mask sheet in an arrangement direction of the middle-sized openings and attaching the blocking part in a transverse direction at the lower side of the large-sized opening to the supporting frame;
attaching the blocking part in the transverse direction at an edge of the mask sheet of lower sides of the middle-sized openings and the small-sized openings to the supporting frame;
attaching the blocking part in a vertical direction between the middle-sized openings to the supporting frame;
attaching the blocking part in the vertical direction at an edge of the mask sheet adjacent to the large-sized opening and the small-sized openings to the supporting frame; and
attaching the blocking part in the transverse direction at an upper side of the large-sized opening to the supporting frame.

13. The method of claim 8, wherein the mask sheet includes a large-sized opening, a plurality of middle-sized openings vertically arranged at first and second sides of the large-sized opening, and a plurality of small-sized openings transversely arranged at third and fourth sides of the large-sized opening.

14. The method of claim 13, wherein attaching the blocking part to the supporting frame comprises:
extending the mask sheet in a transverse direction and attaching the blocking part in a vertical direction between the large-sized opening and the middle-sized openings to the supporting frame;
extending the mask sheet in the vertical direction and attaching the blocking part in the transverse direction between the large-sized opening and the small-sized openings to the supporting frame;
attaching the blocking part in the transverse direction between the middle-sized openings to the supporting frame;
attaching the blocking part formed at the outermost side of the mask sheet adjacent to the middle-sized and small-sized openings to the supporting frame; and
attaching the blocking part in the vertical direction between the small-sized openings to the supporting frame.

15. A method of manufacturing an organic electroluminescent display device, the method comprising:
forming a thin film transistor on a substrate comprising at least two display elements with different sizes from each other;
forming a first electrode connected to the thin film transistor;
forming a bank insulation layer exposing the first electrode;
aligning a deposition mask with the substrate, wherein the deposition mask comprises a mask sheet having openings respectively exposing at least a portion of the at least two display elements, a supporting frame supporting the mask sheet, a mask frame supporting the mask sheet, and wherein the openings correspond to a display area of the display elements;
depositing an organic material on the display area of the substrate to form an organic layer; and
forming a second electrode on the organic layer.

16. The method of claim 15, further comprising forming red, green, and blue color filters in red, green, and blue sub-pixel areas, respectively, wherein each color filter overlaps the first electrode.

17. The method of claim 16, further comprising forming a planarization layer comprising a contact hole connected to the thin film transistor.

18. The method of claim 15, wherein forming the organic layer comprises:
preparing a deposition source to face the deposition mask; and
forming a hole injection layer, a hole transport light, a light emitting layer, an electron transport layer, and an electron injection layer by vaporizing the organic material using the deposition source.

19. The method of claim 18, wherein the light emitting layer includes a plurality of color layers to realize a variety of colors.
